(19) United States
(12) Patent Application Publication
(10) Pub. No.: US 2017/0222026 A1
(43) Pub. Date: Aug. 3, 2017

(54) METHOD OF FABRICATING FIN FIELD EFFECT TRANSISTOR

(71) Applicant: UNITED MICROELECTRONICS CORP., Hsin-Chu City (TW)

(72) Inventors: Yi-Ren Chen, Kaohsiung City (TW); Shou-Wei Hsieh, Hsin-Chu City (TW); Hsin-Yu Chen, Nantou County (TW); Chun-Hao Lin, Kaohsiung City (TW); Yuan-Ting Chuang, Yilan County (TW); Che-Hung Liu, Tainan City (TW)

(21) Appl. No.: 15/014,037

(22) Filed: Feb. 3, 2016

(51) Int. Cl. H01L 29/66; H01L 21/311; H01L 21/28

(52) U.S. Cl. CPC H01L 29/66795; H01L 29/66545; H01L 21/28088; H01L 21/28185; H01L 21/31111

(57) ABSTRACT

The present invention provides a method of fabricating a fin field effect transistor (finFET), comprising: firstly, an interfacial layer is formed on a fin structure, next, a high-k dielectric layer is formed on the interfacial layer; afterwards, a stress film is formed on the high-k dielectric layer, an annealing process is then performed to the stress film, and an etching process is performed to remove the stress film.

### BACKGROUND OF THE INVENTION

1. Field of the Invention

The present invention relates to a method of fabricating a fin field effect transistor (finFET) , and more particularly, to a method of fabricating a finFET having strained channel region.

2. Description of the Prior Art

As semiconductor devices switching speeds continue to increase and operating voltage levels continue to decrease, the performances of metal-oxide-semiconductor field effect transistors (MOSFETs) and other types of transistors need to be correspondingly improved. Currently, along with the development of the MOSFETs, one of the main goals is to increase the carrier mobility so as to further increase the operation speed of the MOSFETs.

In general, a MOSFET is disposed on a semiconductor substrate, which has at least a gate structure, a source region, a drain region separately disposed on two sides of the gate structure and a channel region disposed in the semiconductor substrate right below the gate structure. When a voltage with a certain value is applied to the gate structure, the resistance of the channel region decreases correspondingly, due to the induced capacitance effect and due to the carriers that are able to flow between the source region and the drain region freely. In theory, it is well-known that the mobility of carriers flowing in the channel region can be affected by a lattice structure within the channel region. In order to get benefits from this phenomenon, in the current fabrication processes, a stress layer will be formed on a semiconductor substrate to cover a corresponding gate structure, a source region and a drain region, so as to transfer or apply the inherent stress to the predetermined channel region disposed below the gate structure. However, to carry out a heat treatment process is necessary for the stress transferring process, and this process will bring heat effect to the device on the semiconductor substrate, inducing process variation and side effects. In addition, since there is still a gate structure disposed between the stress layer and the predetermined channel region, the effect of stress transferring process is limited. As a result, it is still an important issue for the manufacturer to provide a method of fabricating a FET in which the inherent stress of the stress layer can be directly transferred to the corresponding channel region more effectively without inducing process variation.

### SUMMARY OF THE INVENTION

One objective of the present invention is to provide a method of fabricating a finFET with a stressed or strained channel by performing the SMT process after removing the dummy gate.

The present invention provides a method of fabricating a fin field effect transistor (finFET), comprising: firstly, an interfacial layer is formed on a fin structure, next, a high-k dielectric layer is formed on the interfacial layer; afterwards, a stress film is formed on the high-k dielectric layer, an annealing process is then performed to the stress film, and an etching process is performed to remove the stress film.

According to the present invention, the SMT process and the DPN process are carried out simultaneously after the high-K layer is formed in the gate trench, but before the BBM, layer is formed. In the SMT process, the stress film is directly formed in the gate trench, which is very close to the fin structure disposed below the gate trench since there may be only one or a few thin layers with about angstrom-grade thickness disposed therebetween. As a result, the SMT provides a superior effect for keeping the stress in the channel region. Furthermore, only one thermal annealing process is carried out for performing the DPN process and the SMT process simultaneously, and therefore the heat affect is lowered. As a result, the present invention provides a method of fabricating the finFET with a stressed channel region to enhance mobility gain through simplified process, without inducing process variation and lowering the side effects of the SMT process.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a flow chart illustrating a method of fabricating a finFET according to a first embodiment of the present invention.

FIGS. 2-10 are schematic drawings illustrating the method of fabricating a finFET according to a first embodiment of the present invention, wherein

FIG. 2 is a schematic three dimensional drawing of the devices mentioned in the first embodiment;

FIG. 3 is a schematic drawing of cross-sectional views of the devices shown in FIG. 2;

FIG. 4 is a schematic drawing in a step subsequent to FIG. 3;

FIG. 5 is a schematic drawing in a step subsequent to FIG. 4;

FIG. 6 is a schematic drawing in a step subsequent to FIG. 5;

FIG. 7 is a schematic drawing in a step subsequent to FIG. 6;

FIG. 8 is a schematic drawing in a step subsequent to FIG. 7;

FIG. 9 is a schematic drawing in a step subsequent to FIG. 8; and

FIG. 10 is a schematic drawing in a step subsequent to FIG. 9.

### DETAILED DESCRIPTION

To provide a better understanding of the present invention to users skilled in the technology of the present invention, preferred embodiments are detailed as follows. The preferred embodiments of the present invention are illustrated in the accompanying drawings with numbered elements to clarify the contents and the effects to be achieved.

Please note that the figures are only for illustration and the figures may not be to scale. The scale may be further modified according to different design considerations. When referring to the words “up” or “down” that describe the relationship between components in the text, it is well known in the art and should be clearly understood that these words refer to relative positions that can be inverted to obtain a similar structure, and these structures should therefore not be precluded from the scope of the claims in the present invention.

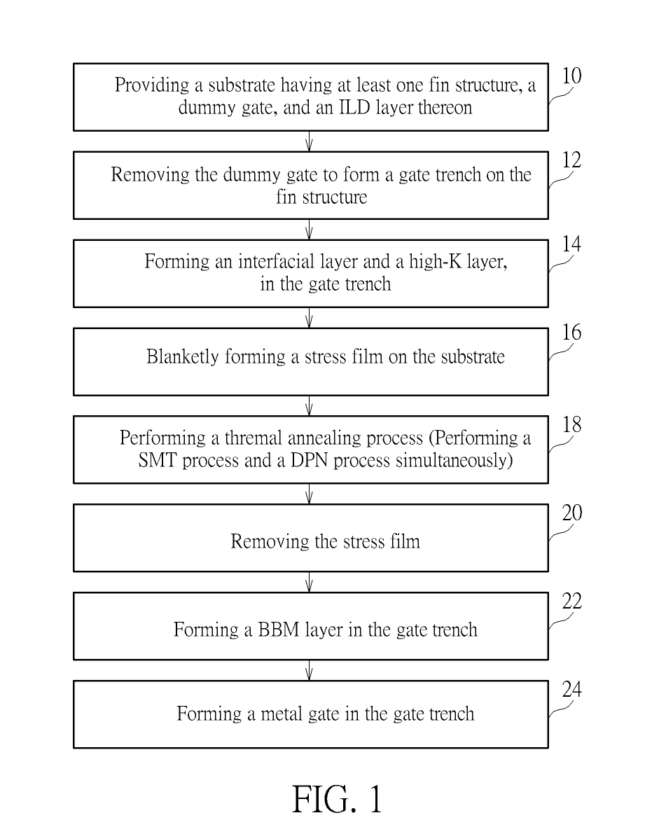

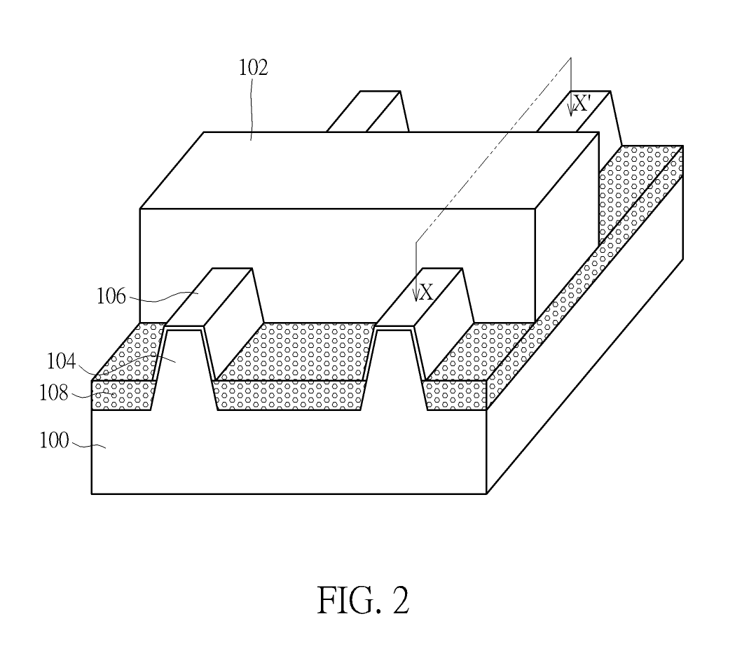

Please refer to FIG. 1 and FIGS. 2-10, wherein FIG. 1 is a flow chart illustrating a method for fabricating a finFET according to a first embodiment provided by the present invention, and FIGS. 2-10 are schematic drawings illustrating the method for fabricating a finFET according to the first embodiment of the present invention. As shown in FIG. 1, the present invention performs STEP 10: providing a substrate having at least one fin structure, a dummy gate, and an ILD layer thereon, wherein the dummy gate covers a portion of the fin structure. Referring to FIGS. 2-3, a substrate 100 is first provided, wherein FIG. 3 shows the cross-sectional view along the cross line X-X′ of FIG. 2. The substrate 100 has at least one fin structure 104, wherein two fin structures 104 are shown for illustration in FIGS. 2-3. The substrate 100 may be, for example, a silicon substrate, a silicon-containing substrate, a III-V group-on-silicon (such as GaN-on-silicon) substrate or a graphene-on-silicon substrate, but is not limited thereto. An isolation structure 108 (ex. an oxide layer) may be formed between each of the fin structures 104 by successively performing a deposition, a planarization, and an etching back process. As shown in FIG. 2, the isolation structure 108 may be formed between each fin structure 104 parallel to each other, thus good isolation may be provided for the devices formed in following process. In addition, a gate insulating layer 106 and a dummy gate 102 are disposed on the surface of the substrate 100, covering a portion of the fin structures 104, wherein the gate insulating layer 106 is disposed between the fin structures 104 and the dummy gate 102. The dummy gate 102 may be formed by a patterned polysilicon layer. The gate insulating layer 106 may be composed of oxide layer, for instance. Although the gate insulating layer 106 covers the top surface of the fin structures 104 in FIGS. 2-3, it may be selectively removed from the top surface of the exposed fin structures 104 when patterning the polysilicon layer for forming the dummy gate 104 in other variant embodiments, which means no gate insulating layer 106 will be left on the surface of the exposed fin structures 104.

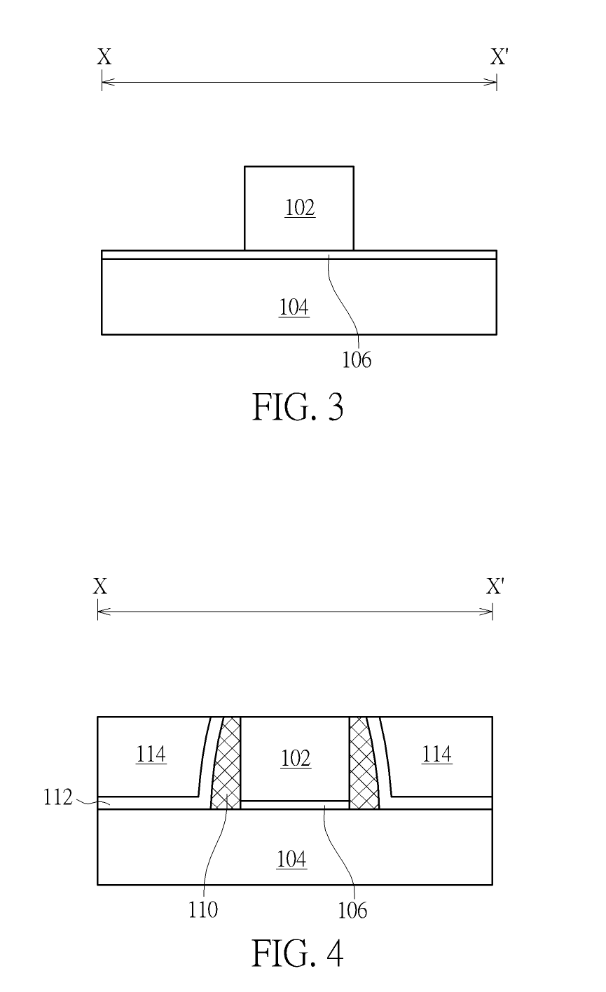

Then, referring to FIG. 4, after removing the gate insulating layer 106 not covered by the dummy gate 102, a spacer 110, source and drain regions (not shown), a contact etch stop layer (CESL) 112, and an ILD layer 114 are sequentially formed on the substrate 100. The spacer 110 is formed on the sidewall of the dummy gate 102, by depositing a material layer and then performing a dry etching process on said material layer, for instance. The CESL 112 may include nitride silicon material, but is not limited to. The source and drain regions may be formed through a heavy doping process in the fin structure 104 near the spacer 110. The ILD layer 114 may be formed by depositing a dielectric material layer and a chemical mechanism polishing (CMP) process to remove the excessive dielectric material layer higher than the dummy gate 102. In this embodiment, the dummy gate 102 is exposed by the ILD layer 114, as shown in the X-X′ section part in FIG. 4.

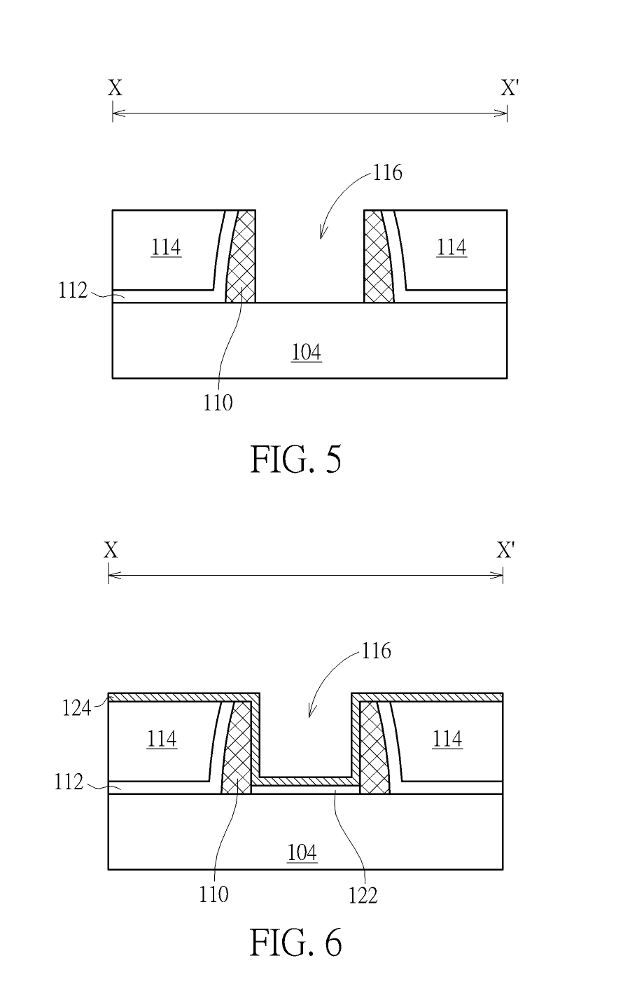

Please refer to FIG. 1 and FIG. 5. The present invention then performs STEP 12: removing the dummy gate to form a gate trench on the fin structure. As shown in FIG. 5, a dummy gate removal process is than carried out to remove the dummy gate 102 shown in FIG. 4. In this dummy gate removal process, a dry etching process may be performed to remove the majority of polysilicon from the dummy gate 102, and a wet etching may be further conducted to remove the remaining dummy gate 102. After the dummy gate 102 is removed, the gate insulating layer 106 can also be selectively removed through another etching process, a gate trench 116 is formed between the spacers 110, and the fin structure 104 mentioned above is exposed.

Please refer to FIG. 1 again and FIG. 6. STEP 14 is then performed to selectively form an interfacial layer and a high-K dielectric layer in the gate trench 116. As shown in FIG. 6, an interfacial layer 122 is optionally formed in the bottom surface of the gate trench 116 and the top surfaces of the fin structures 104, through an in-situ steam generation (ISSG) process, in which the interfacial layer 122 is composed of silicon oxide and the thickness thereof is around 10 Angstroms for example. One of the main functions of the interfacial layer 122 is to facilitate the adhering between the following formed high-K dielectric layer 124 and the exposed fin structures 104 in a subsequent process. Then, a high-K dielectric layer 124 is deposited on the interfacial layer 122 and the surface of the spacer 110, the ILD layer 114 and the fin structures 104. The high-K dielectric layer 124 may be formed through an atomic layer deposition (ALD) process. In this embodiment, the high-K dielectric layer 124 could be a single-layer or a multi-layer structure containing metal oxide layer such as rare earth metal oxide, wherein the dielectric constant of the high-K dielectric layer 124 is substantially greater than 20. For example, the high-K dielectric layer 124 could be selected from a group consisting of hafnium oxide (HfO₂), hafnium silicon oxide (HfSiO), hafnium silicon oxynitride (HfSiON), aluminum oxide (AlO), lanthanum oxide (La₂O₃), lanthanum aluminum oxide (LaAlO), tantalum oxide, Ta₂O₃, zirconium oxide (ZrO₂), zirconium silicon oxide (ZrSiO), hafnium zirconium oxide (HfZrO), strontium bismuth tantalite (SrBi₂Ta₂O₉, SBT), lead zirconate titanate (PbZrₓTi₁₋ₓO₃, PZT), and barium strontium titanate (BaₓSr₁₋ₓTiO₃, BST). The thickness of the high-k dielectric layer 124 may be about 20 Angstroms, but is not limited thereto.

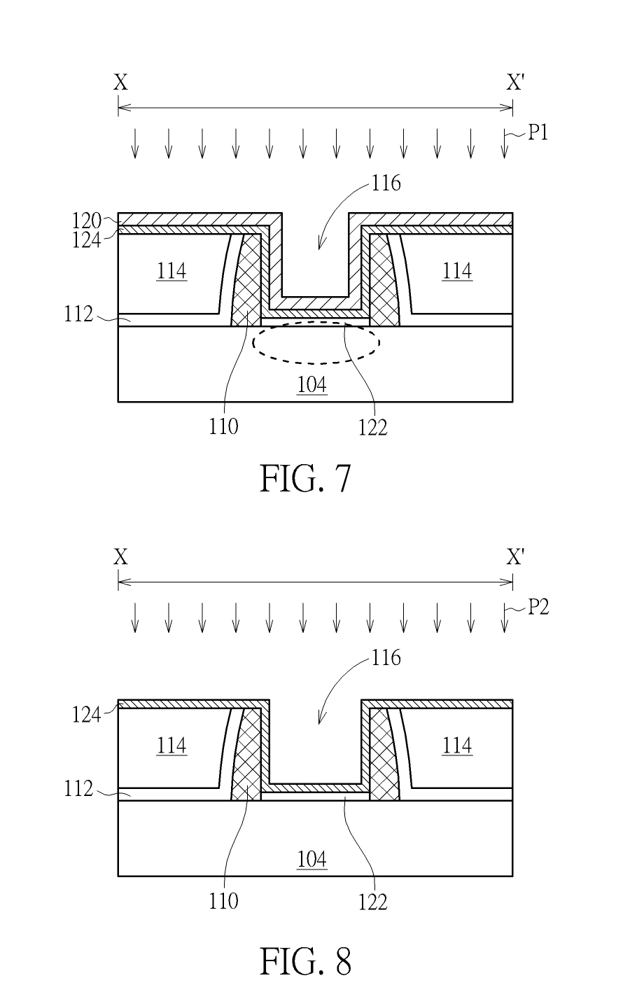

Next, please refer to FIG. 1 again and FIG. 7. STEP 16 is performed to blanketly form a stress film on the substrate. A stress film 120 is blanketly formed on the substrate 100 to cover the surface of the gate trench 116 and the top surfaces of the fin structures 104. The stress film 120 may be, but is not limited to, a silicon nitride layer or a silicon carbonitride (SiCN) layer, and may be formed through a deposition processes, such as a plasma-enhanced chemical vapor deposition (PECVD) process, a sub-atmospheric pressure chemical vapor deposition (SACVD) process, and a high-density plasma chemical vapor deposition (HDCVD) process. In addition, optionally, a buffer layer (not shown) may be conformally formed on the surface of the substrate 100 before forming the stress film 120 in order to enhance the adhering of the stress film 120 or to protect the spacer 110 and other device on the substrate 100 in the subsequent process. The processes for forming the buffer layer may include a CVD process or a high temperature oxidation process, but is not limited thereto. The buffer layer is, but is not limited to, a silicon oxide layer in this embodiment. It is worth noting that the buffer layer is not a necessary element for the present invention, and the process of forming the buffer layer can be omitted if required.

Next, STEP 18 shown in FIG. 1 is performed to carry out a thermal annealing process. The thermal annealing process P1 is subsequently carried out to the stress film 120 for conducting a stress memorization technique (SMT) process on the fin structures 104. The thermal annealing process P1 may be performed between 400° C. to 900° C., but is not limited thereto. The silicon atoms in the fin structures 104 will be re-crystallized according to the tensile/compressive directions that the stress film 120 provides, so as to form a strained channel region (marked by the dotted circle in FIG. 7) below the gate trench 116. It is noteworthy that when the predetermined formed finFET is an N type finFET, the strained channel is a tensile strain channel, and when the predetermined formed finFET is a P type finFET, the strained channel is a compressive strain channel. In this embodiment, the predetermined formed finFET is an N type finFET, and the stress film 120 formed in STEP 18 is a tensile stress film, which provides a good longitudinal stress of the FET.

Besides, during the thermal annealing process P1, a decoupled plasma nitridation (DPN) process can be performed with the SMT process simultaneously. More precisely, an N₂ plasma can be introduced during the thermal annealing process P1, thereby driving the nitrogen atoms into the high-K layer 124 and the interfacial layer 122 during the thermal annealing process P1, so as to improve the reliability of the finFET or the MOSFET. For example, the time-dependent dielectric breakdown (TDDB) of the finFET or the MOSFET can be increased. In another case, according to applicant's experiment, if the temperature of the thermal annealing process is higher than 1000° C., the nitrogen atoms in the stress film (such as a SiN layer) can also be driven into the high-K layer 124 and the interfacial layer 122 without introducing the N₂ plasma. In this case, the N₂ plasma process can be selectively omitted if required.

It is noteworthy that in one embodiment of the present invention, the DPN process and the SMT process can be performed simultaneously. However, the present invention is not limited thereto. In another case of the present invention, the DPN process and the SMT process can be performed in different steps, in other words, the DPN process can be performed before or after the SMT process is performed, and it should also be within the scope of the present invention.

It is noteworthy that in the present invention, the stress film 120 does not comprise metal atoms (or with metal nitride materials) or polysilicon, for example, the stress film 120 is not a titanium oxide (TiN) layer or a polysilicon layer. The reason for using the stress film without metal atoms or polysilicon is that in a conventional process, a bottom barrier (BBM) layer, such as a TiN layer is usually sequentially formed on the high-K layer 124 for protecting the high-K layer 124, but during the thermal anneal process P1 mentioned above, if the layer covered on the high-K layer 124 is a metal nitride layer with metal atoms (such as a TiN layer) or a polysilicon layer, a grain boundary is easy to be formed within the structure of the TiN layer or the polysilicon layer while the temperature is high (about higher than 600° C.). It causes an issue that the oxygen atoms in the air can easily “penetrate through” the TiN layer or the polysilicon layer through the grain boundary, and thereby influence the high-K layer 124 and the interfacial layer 122 during the thermal anneal process Pl. In order to prevent the issue from occurring, one solution is to further form an oxygen-absorption material layer (such as an amorphous silicon layer) on the TiN layer or on the polysilicon layer to absorb oxygen from the TiN layer, the polysilicon layer or the air. The oxygen-absorption material layer covers on the TiN layer or the polysilicon layer, preventing the oxygen atoms in the air from penetrating the TiN layer or the polysilicon layer during the thermal anneal process. However, forming the oxygen-absorption material layer also makes the manufacturing process more complicated and the cost is increased too.

In the present invention, the stress film 120 (such as a silicon nitride layer) formed on the high-K layer 124 is not a TiN layer or a polysilicon layer, so the grain boundary is not easy to form in the stress film 120 during the thermal anneal process P1, and oxygen atoms in the air will not penetrate the stress film 120. In this way, the step for forming the oxygen-absorption material layer (such as amorphous silicon layer) can be omitted too. Furthermore, as mentioned above, the SMT process and the DPN process can be performed simultaneously in one thermal anneal process. Therefore, the manufacturing processes can be simplified.

Afterwards, please refer to FIG. 1 again and FIG. 8. STEP 20 is then performed after the thermal annealing process Pl. The stress film 120 may be removed through an etching process P2, as shown in FIG. 8. It is noteworthy that since both the high-K layer 124 and the stress film 120 are made of dielectric materials (for example, the high-K layer 124 is a HfO₂, and the stress film 120 is a SiN layer) , the stress film is difficult to be removed individually through a normal etching process, such as a dilute hydrofluoric (dHF) acid containing cleaning process. More, precisely, because the etching rate for etching the high-K layer 124 is similar to the etching rate for etching the stress film 120 while using the dHF as the etchant, the high-K layer 124 is easy to be damaged while removing the stress film 120. In this embodiment, the etching process P2 does not comprise a dilute hydrofluoric acid containing cleaning process, and the etching process P2 is a Standard Clean 1 (SC1) process. According to applicant's experiment, the etching rate for etching the stress film 120 (such as SiN) is much faster than the etching rate for etching the high-K layer 124, and the etching rate ratio is about 200:1. Therefore, in the present invention, using the SC1 process as the etchant of the etching process P2, has the effects of removing the stress film 120 completely but not removing or damaging the high-K layer 124 disposed below.

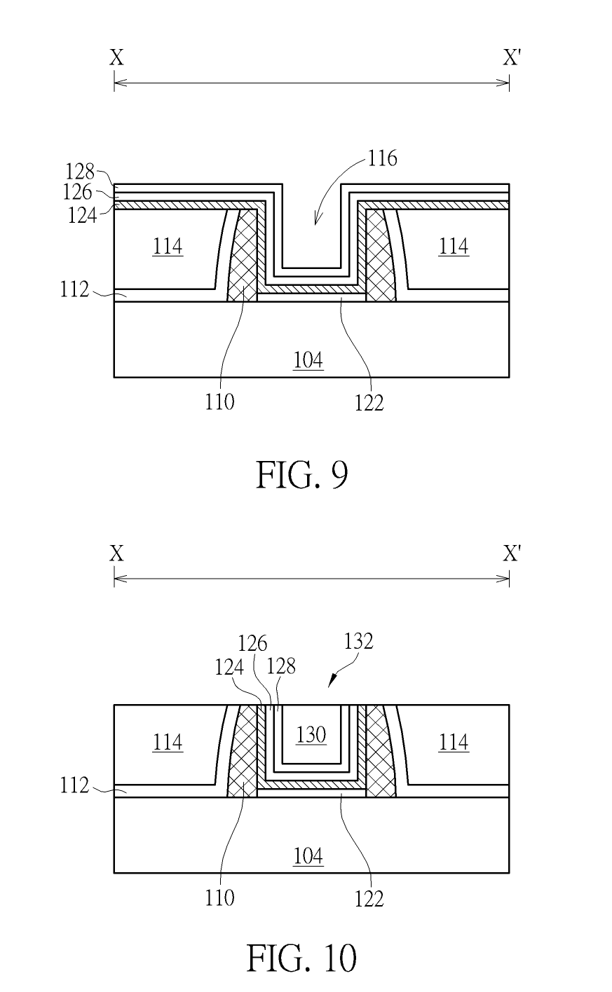

Next, please refer to FIG. 1 again and FIG. 9. STEP 22 is performed to form a bottom barrier metal (BBM) layer 126 on the high-K dielectric layer 124 and contacts the high-K dielectric layer 124 directly. For example, the BBM layer 126 is composed of tantalum nitride (TaN), but is not limited thereto. It should be noted that as mentioned above, the TiN layer is not need to be formed on the high-K dielectric layer 124, so preferably, the BBM layer 126 is not a TiN layer or a polysilicon layer.

Please refer to FIG. 1 again and FIG. 10. STEP 24 is performed to form a metal gate in the gate trench. In FIG. 10 a work function metal layer 128 may be selectively formed on the substrate 100 to cover the surface of the BBM layer 126. Then, a conductive layer 130 with low resistance material is deposited to fill the gate trench 116. Sequentially, one or multiple planarizing processes, such as a chemical mechanical polishing (CMP) process is carried out to partially remove the conductive layer and the work function metal layer to form a metal gate 132 in the gate trench 116. It should be noted that the material of the work function metal layer is selected depending on the conductivity type of the finFET. As this approach is well known to those skilled in the art, the details of which are not described herein for sake of brevity. The fabrication of the finFET according to the present invention is complete.

In summary, according to the present invention, the SMT process and the DPN process are carried out simultaneously after the high-K layer is formed in the gate trench, but before the BBM layer is formed. In the SMT process, the stress film is directly formed in the gate trench, which is very close to the fin structure disposed below the gate trench since there may be only one or a few thin layers with about angstrom-grade thickness disposed therebetween. As a result, the SMT provides a superior effect for keeping the stress in the channel region. Furthermore, only one thermal annealing process is carried out for performing the DPN process and the SMT process simultaneously, and therefore the heat affect is lowered. As a result, the present invention provides a method of fabricating the finFET with a stressed channel region to enhance mobility gain through simplified process, without inducing process variation and lowering the side effects of the SMT process.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of fabricating a fin field effect transistor (finFET), comprising:
forming an interfacial layer on a fin structure;
forming a high-k dielectric layer on the interfacial layer;
forming a stress film on the high-k dielectric layer;
performing an annealing process on the stress film; and
performing an etching process to remove the stress film.

2. The method of claim 1, wherein the stress film comprises a silicon nitride layer or a silicon carbonitride (SiCN) layer.

3. The method of claim 1, wherein stress film does not comprise a metal nitride layer.

4. The method of claim 1, wherein the stress film does not comprise a polysilicon layer.

5. The method of claim 1, wherein the high-k layer is not removed after the etching process for removing the stress film is performed.

6. The method of claim 5, wherein the etching process comprises a Standard Clean 1 (SC1) process.

7. The method of claim 1, wherein the etching process does not comprise a dilute hydrofluoric acid containing cleaning process.

8. The method of claim 1, further comprising forming a bottom barrier layer (BBM) after the stress film is removed.

9. The method of claim 8, wherein the bottom barrier layer comprises a tantalum nitride (TaN) layer.

10. The method of claim 9, wherein the BBM directly contacts the high-k dielectric layer.

11. The method of claim 8, wherein the BBM does not comprise a titanium nitride (TiN) layer.

12. The method of claim 1, wherein the anneal process is performed with a N₂ plasma.

13. The method of claim 12, wherein the temperature of the anneal process is between 400° C. and 900° C.

14. The method of claim 1, wherein the anneal process is performed without a N₂ plasma.

15. The method of claim 14, wherein the temperature of the anneal process is higher than 1000° C.

16. The method of claim 1, further comprising forming a metal gate in the gate trench.

17. The method of claim 1, further comprising forming an ILD on a substrate, and a dummy gate is disposed in the ILD, wherein the dummy gate covers a portion of the fin structure.

18. The method of claim 7, further comprising removing the dummy gate to form the gate trench.
